(19) United States
(12) Patent Application Publication
(10) Pub. No.: US 2024/0306467 A1
(43) Pub. Date: Sep. 12, 2024

(54) DISPLAY DEVICE AND ELECTRONIC APPARATUS

(71) Applicant: SEIKO EPSON CORPORATION, Tokyo (JP)

(72) Inventors: Jun IROBE, Suwa-shi (JP); Yuiga HAMADE, Matsumoto-shi (JP)

(73) Assignee: SEIKO EPSON CORPORATION, Tokyo (JP)

(21) Appl. No.: 18/596,601

(22) Filed: Mar. 5, 2024

(30) Foreign Application Priority Data
Mar. 7, 2023 (JP) 2023-034529

(51) Int. Cl. H10K 59/38; H10K 59/80

(52) U.S. Cl. CPC H10K 59/38; H10K 59/871; H10K 59/879

(57) ABSTRACT

Provided is a display device including: a first colored layer provided at an opposite side of a first light-emitting element with respect to a sealing layer; and a second colored layer provided at an opposite side of a second light-emitting element with respect to the sealing layer. The first colored layer includes a first flat surface at an opposite side of the sealing layer, a first side surface in contact with the second colored layer, and a first coupling surface inclined with respect to the first flat surface, coupling the first flat surface and the first side surface, and separated from the second colored layer. The second colored layer includes a second flat surface at the opposite side of the sealing layer, a second side surface in contact with the first side surface, and a second coupling surface inclined with respect to the second flat surface, coupling the second flat surface and the second side surface, and separated from the first colored layer. A contact portion between the first side surface and the second side surface contacts with the sealing layer.

The present application is based on, and claims priority from JP Application Serial Number 2023-034529, filed Mar. 7, 2023, the disclosure of which is hereby incorporated by reference herein in its entirety.

### BACKGROUND

### 1. Technical Field

The present disclosure relates to a display device and an electronic apparatus.

### 2. Related Art

There has been known a display device including a light-emitting element such as an organic electroluminescence (EL) element.

For example, JP-A-2022-26073 describes an electro-optical device including a substrate, a first light-emitting element and a second light-emitting element, a sealing layer disposed on the first light-emitting element and the second light-emitting element, a first colored portion transmitting light from the first light-emitting element, a second colored portion transmitting light from the second light-emitting element, and a wall portion in contact with the sealing layer and provided between a first colored layer and a second colored layer.

In the electro-optical device described above, it is desired to improve color purity.

### SUMMARY

According to an aspect of the present disclosure, there is provided a display device including a substrate, a first light-emitting element and a second light-emitting element provided at the substrate, a sealing layer covering the first light-emitting element and the second light-emitting element, a first colored layer that is provided at an opposite side of the first light-emitting element with respect to the sealing layer and through which light from the first light-emitting element passes, and a second colored layer that is provided at an opposite side of the second light-emitting element with respect to the sealing layer and through which light from the second light-emitting element passes. The first colored layer includes a first flat surface at an opposite side of the sealing layer, a first side surface in contact with the second colored layer, and a first coupling surface inclined with respect to the first flat surface, coupling the first flat surface and the first side surface, and separated from the second colored layer. The second colored layer includes a second flat surface at the opposite side of the sealing layer, a second side surface in contact with the first side surface, and a second coupling surface inclined with respect to the second flat surface, coupling the second flat surface and the second side surface, and separated from the first colored layer. A contact portion between the first side surface and the second side surface is in contact with the sealing layer.

According to another aspect of the present disclosure, there is provided an electronic apparatus including the display device of the aspect described above.

### BRIEF DESCRIPTION OF THE DRAWINGS

FIG. 1 is a plan view schematically illustrating a display device according to the present embodiment.

FIG. 2 is an equivalent circuit diagram illustrating a sub-pixel of a display device according to the present embodiment.

FIG. 3 is a plan view schematically illustrating a display device according to the present embodiment.

FIG. 4 is a cross-sectional view schematically illustrating a display device according to the present embodiment.

FIG. 5 is a cross-sectional view schematically illustrating a display device according to the present embodiment.

FIG. 6 is a cross-sectional view schematically illustrating a display device according to the present embodiment.

FIG. 7 is a cross-sectional view schematically illustrating a display device according to a reference example.

FIG. 8 is a cross-sectional view schematically illustrating a manufacturing step of a display device according to the present embodiment.

FIG. 9 is a cross-sectional view schematically illustrating a manufacturing step of a display device according to the present embodiment.

FIG. 10 is a cross-sectional view schematically illustrating a manufacturing step of a display device according to the present embodiment.

FIG. 11 is a cross-sectional view schematically illustrating a manufacturing step of a display device according to the present embodiment.

FIG. 12 is a cross-sectional view schematically illustrating a manufacturing step of a display device according to the present embodiment.

FIG. 13 is a cross-sectional view schematically illustrating a manufacturing step of a display device according to the present embodiment.

FIG. 14 is a cross-sectional view schematically illustrating a display device according to a first modification example of the present embodiment.

FIG. 15 is a cross-sectional view schematically illustrating a display device according to a second modification example of the present embodiment.

FIG. 16 is a cross-sectional view schematically illustrating a display device according to a third modification example of the present embodiment.

FIG. 17 is a plan view schematically illustrating a display device according to a fourth modification example of the present embodiment.

FIG. 18 is a perspective view schematically illustrating a head-mounted display according to the present embodiment.

FIG. 19 is a diagram schematically illustrating an image forming device and light-guide device of a head-mounted display according to the present embodiment.

FIG. 20 is a table showing light extraction efficiency in Example 1 and Comparative Example 1.

FIG. 21 is a table showing a measurement result of a color gamut in Example 1 and Comparative Example 1.

FIG. 22 is a CIE1931 color space showing a measurement result of a color gamut in Example 1 and Comparative Example 1.

### DESCRIPTION OF EMBODIMENTS

A preferred embodiment of the present disclosure will be described below in detail with reference to the drawings. Note that the embodiment described below do not unduly limit the content of the present disclosure described in the claims. Furthermore, not all the configurations described below are essential constituent elements of the present disclosure.

### 1. Display Device

### 1.1. Overall Configuration

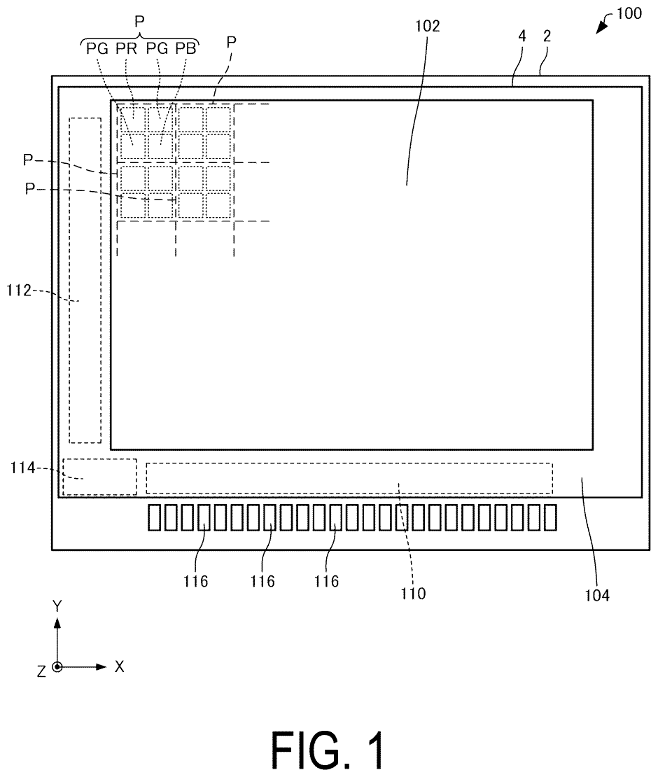

First, a display device according to the present embodiment is described with reference to the drawings. FIG. 1 is a plan view schematically illustrating a display device 100 according to the present embodiment. An X-axis, a Y-axis, and a Z-axis are illustrated in FIG. 1 as three axes orthogonal to each other.

For example, the display device 100 is a device that displays a full-color image using organic EL. The image includes those only displaying character information. The display device 100 is, for example, a micro display suitably used for a head-mounted display or the like.

As illustrated in FIG. 1, the display device 100 includes a display region 102 that displays an image and a peripheral region 104 that surrounds the periphery of the display region 102 in plan view. In the illustrated example, a plan view is a view from a Z-axis direction. The planar shape of the display region 102 is, for example, a quadrangle.

The display device 100 includes a plurality of pixels P. The pixels P are provided in the display region 102. Each of the pixels P is a minimum unit in displaying an image. In the illustrated example, the pixels P are arranged in a matrix in an X-axis direction and a Y-axis direction.

Each of a plurality of the pixels P of the display device 100 includes a red sub-pixel PR that emits red light, a green sub-pixel PG that emits green light, and a blue sub-pixel PB that emits blue light. In the illustrated example, one red sub-pixel PR is provided in one pixel P. Two green sub-pixels PG are provided. One blue sub-pixel PB is provided. The sub-pixels PR, PG, and PB constitute one pixel P of the color image. The wavelength range of the red light emitted from the red sub-pixel PR is longer than 580 nm and equal to or shorter than 700 nm. The wavelength range of the green light emitted from the green sub-pixel PG is equal to or longer than 500 nm and equal to or shorter than 580 nm. The wavelength range of the blue light emitted from the blue sub-pixel PB is equal to or longer than 400 nm and shorter than 500 nm. For the sake of convenience, in FIG. 1, the sub-pixels PR, PG, and PB are illustrated in a simplified manner.

The display device 100 includes, for example, an element substrate 2 and a light-transmitting substrate 4. The element substrate 2 and the light-transmitting substrate 4 are layered in the Z-axis direction. The display device 100 has a so-called top emission structure and emits light from the light-transmitting substrate 4.

The element substrate 2 includes, for example, a data line drive circuit 110, a scanning line drive circuit 112, a control circuit 114, and a plurality of external terminals 116. The data line drive circuit 110, the scanning line drive circuit 112, the control circuit 114, and a plurality of the external terminals 116 are provided in the peripheral region 104. The data line drive circuit 110 and the scanning line drive circuit 112 are peripheral circuits that control driving of the sub-pixels PR, PG, and PB. The control circuit 114 controls image display. Image data is supplied to the control circuit 114 from a higher-level circuit (not illustrated). The control circuit 114 supplies various signals based on the image data to the data line drive circuit 110 and the scanning line drive circuit 112. Although not illustrated, a flexible printed circuit (FPC) board or the like (not illustrated) for electrical coupling with the higher-level circuit is coupled to the external terminals 116. A power supply circuit (not illustrated) is electrically coupled to the element substrate 2.

The light-transmitting substrate 4 is a cover that protects the element substrate 2. The light-transmitting substrate 4 is, for example, a glass substrate or a quartz substrate. The light-transmitting substrate 4 has a light-transmitting property.

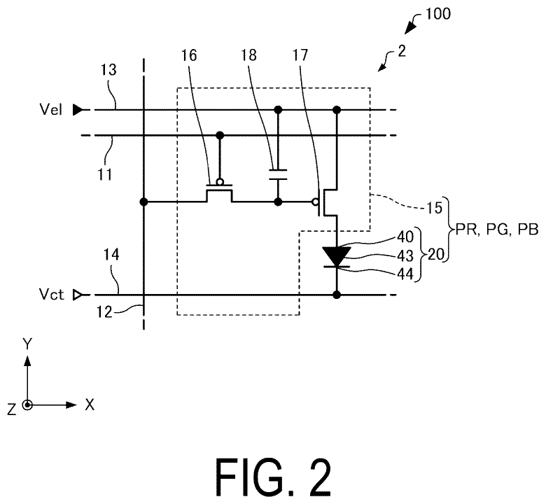

FIG. 2 is an equivalent circuit diagram of the sub-pixels PR, PG, and PB of the display device 100. The element substrate 2 includes, for example, a plurality of scanning lines 11, a plurality of data lines 12, a plurality of first power supply lines 13, and a plurality of second power supply lines 14.

Each of the scanning lines 11 extends, for example, in the X-axis direction. Each of the data lines 12 extends, for example, in the Y-axis direction. Although not illustrated, a plurality of the scanning lines 11 and a plurality of the data lines 12 are arranged in a lattice pattern. The scanning line 11 is coupled to the scanning line drive circuit 112 illustrated in FIG. 1. The data line 12 is coupled to the data line drive circuit 110 illustrated in FIG. 1.

As illustrated in FIG. 2, the sub-pixels PR, PG, and PB include a light-emitting element 20 and a pixel circuit 15 that controls driving of the light-emitting element 20. For example, the light-emitting element 20 is an organic light-emitting diode (OLED). The light-emitting element 20 includes, for example, a pixel electrode 40, a light-emitting layer 43, and a common electrode 44.

Each of the first power supply lines 13 is electrically coupled to the pixel electrode 40 via the pixel circuit 15. Each of the second power supply lines 14 is electrically coupled to the common electrode 44. A power supply potential Vel on a higher potential side is supplied from a power supply circuit (not illustrated) to the first power supply line 13. A power supply potential Vct on a lower potential side is supplied from the power supply circuit (not illustrated) to the second power supply line 14. The pixel electrode 40 serves as an anode. The common electrode 44 serves as a cathode. In the light-emitting element 20, holes supplied from the pixel electrode 40 and electrons supplied from the common electrode 44 are recombined in the light-emitting layer 43. Thus, the light-emitting layer 43 emits light.

The pixel circuit 15 includes, for example, a switching transistor 16, a driving transistor 17, and a holding capacitor 18. The gate of the switching transistor 16 is electrically coupled to the scanning line 11. One of a source and a drain of the switching transistor 16 is electrically coupled to the data line 12, and the other is electrically coupled to a gate of the driving transistor 17. One of a source and a drain of the driving transistor 17 is electrically coupled to the first power supply line 13, and the other is electrically coupled to the pixel electrode 40. One electrode of the holding capacitor 18 is electrically coupled to the gate of the driving transistor 17, and the other electrode is electrically coupled to the first power supply line 13.

In the pixel circuit 15, when the scanning line 11 is selected by the scanning line drive circuit 112 activating a scanning signal, the switching transistor 16 provided in the selected sub-pixels PR, PG, and PB is turned on. Then, the data signal is supplied from the data line 12 to the driving transistor 17 corresponding to the selected scanning line 11. The driving transistor 17 supplies a current corresponding to a potential of the supplied data signal, that is, a current corresponding to a potential difference between the gate and the source, to the light-emitting element 20. Then, the light-emitting element 20 emits light at a luminance corresponding to a magnitude of the current supplied from the driving transistor 17. When the scanning line drive circuit 112 releases the selection of the scanning line 11 and the switching transistor 16 is turned off, the potential of the gate of the driving transistor 17 is held by the holding capacitor 18. Thus, the light-emitting element 20 can maintain light emission of the light-emitting element 20 even after the switching transistor 16 is turned off.

The configuration of the pixel circuit 15 is not limited to the illustrated example. Although not illustrated, for example, the pixel circuit 15 may include a transistor that controls the conduction between the pixel electrode 40 and the driving transistor 17.

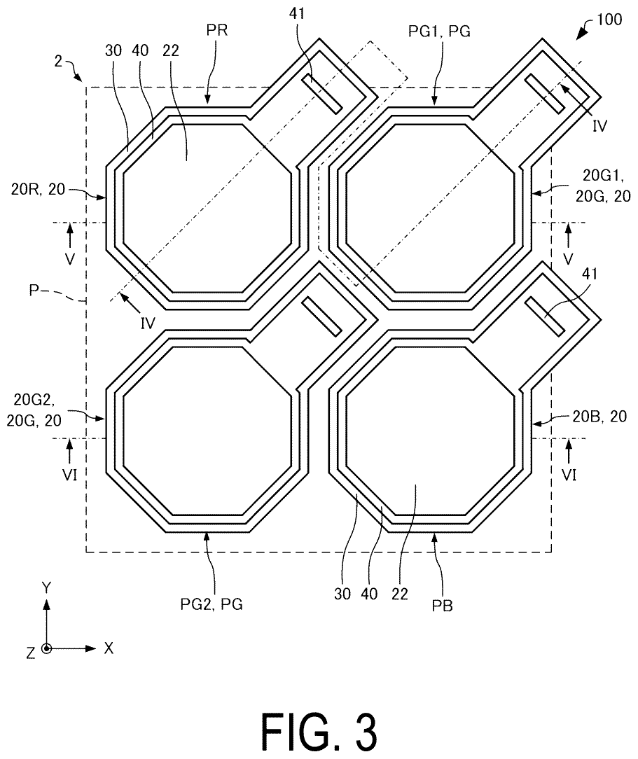

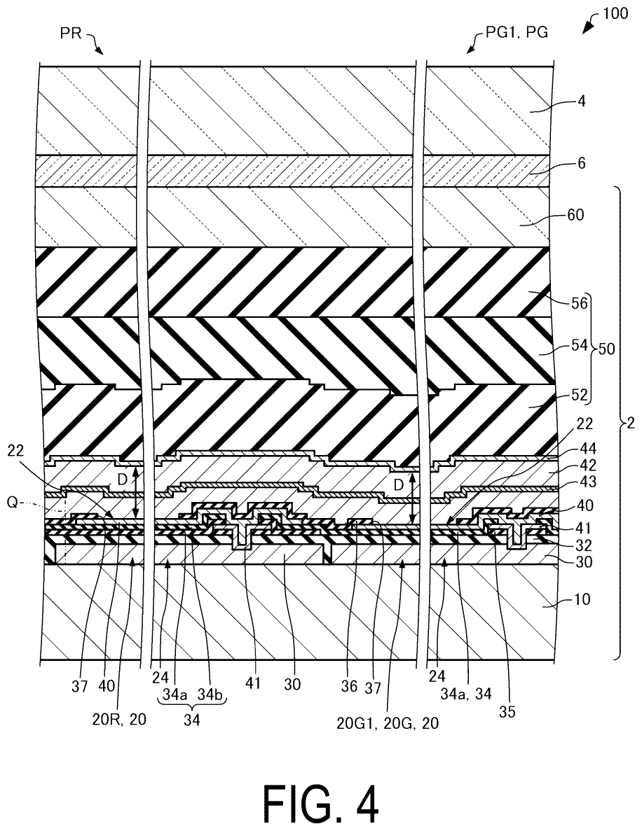

FIG. 3 is a plan view schematically illustrating the display device 100. FIG. 4 is a cross-sectional view taken along line IV-IV of FIG. 3, schematically illustrating the display device 100.

As illustrated in FIG. 3, one pixel P includes a red sub-pixel PR, a green sub-pixel PG, and a blue sub-pixel PB. In the illustrated example, the pixel P includes two green sub-pixels PG1 and PG2 as the green sub-pixel PG. For example, the sub-pixels PR, PG1, PG2, and PB are arranged in a square lattice pattern. In the illustrated example, in one pixel P, the green sub-pixel PG1 is provided at a positive X-axis direction side of the red sub-pixel PR. The green sub-pixel PG2 is provided at a negative Y-axis direction side of the red sub-pixel PR. The blue sub-pixel PB is provided at the positive X-axis direction side of the green sub-pixel PG2.

As illustrated in FIGS. 3 and 4, the element substrate 2 of the display device 100 includes, for example, a substrate 10, a light-emitting element 20, a sealing layer 50, and a colored portion 60. As illustrated in FIG. 4, the light-transmitting substrate 4 is bonded to the element substrate 2 via an adhesive layer 6. For the sake of convenience, FIG. 3 does not illustrate members other than a light-emitting region 22 of the light-emitting element 20, a reflection layer 30, a pixel electrode 40, and contact electrode 41.

The substrate 10 is, for example, a wiring substrate in which the above-described pixel circuit 15 is provided on a silicon substrate. As illustrated in FIG. 4, the substrate 10 has, for example, a perpendicular line Q parallel to the Z-axis. Instead of the silicon substrate, for example, a glass substrate, a resin substrate, or a ceramics substrate may be used. The transistors 16 and 17 of the pixel circuit 15 are, for example, metal-oxide-semiconductors (MOSs) transistor, thin film transistors, or field effect transistors. Examples of materials for the elements and wiring lines of the pixel circuit 15 include, for example, conductive materials such as polysilicon, metals, metal silicide, and metal compounds.

The light-emitting element 20 is provided on the substrate 10. The light-emitting element 20 is provided between the substrate 10 and the sealing layer 50. A plurality of the light-emitting elements 20 are provided corresponding to a plurality of the sub-pixels PR, PG1, PG2, and PB. As illustrated in FIG. 3, the red sub-pixel PR includes a first light-emitting element 20R as the light-emitting element 20. The green sub-pixel PG1 includes a second light-emitting element 20G1 as the light-emitting element 20. The green sub-pixel PG2 includes a third light-emitting element 20G2 as the light-emitting element 20. The blue sub-pixel PB includes a fourth light-emitting element 20B as the light-emitting element 20.

As illustrated in FIG. 4, the light-emitting element 20 includes, for example, a reflection layer 30, an insulation layer 32, an optical path adjustment layer 34, an element isolation layer 36, a pixel electrode 40, an organic layer 42, and a common electrode 44.

The reflection layer 30 is provided on the substrate 10. The reflection layer 30 is provided between the substrate 10 and the insulation layer 32. The reflection layer 30 is individually provided at a plurality of the light-emitting elements 20. The reflection layer 30 is, for example, an aluminum (Al) layer, a silver (Ag) layer, or the like. The reflection layer 30 reflects the light generated in the light-emitting layer 43. The reflection layer 30 is electrically coupled to, for example, the pixel circuit 15.

The insulation layer 32 is provided on the reflection layer 30. The insulation layer 32 is provided between the reflection layer 30 and the optical path adjustment layer 34. The insulation layer 32 is further provided between the adjacent reflection layers 30. The insulation layer 32 is, for example, a silicon nitride layer, a silicon oxide layer, or a silicon oxynitride layer.

The optical path adjustment layer 34 is provided on the insulation layer 32. The optical path adjustment layer 34 is provided between the insulation layer 32 and the pixel electrode 40. The optical path adjustment layer 34 is a layer for adjusting a distance D between the reflection layer 30 and the common electrode 44. The optical path adjustment layer 34 is, for example, a silicon nitride layer, a silicon oxide layer, or a silicon oxynitride layer.

The optical path adjustment layer 34 includes, for example, a first adjustment layer 34a and a second adjustment layer 34b. The first adjustment layer 34a is provided in the red sub-pixel PR, and is not provided in the sub-pixels PG and PB. The second adjustment layer 34b is provided in the sub-pixels PR and PG, and is not provided in the blue sub-pixel PB. In the sub-pixel PR, the second adjustment layer 34b is provided on the first adjustment layer 34a. With the optical path adjustment layer 34, the distance D of the green sub-pixel PG can be made larger than the distance D of the blue sub-pixel PB, and the distance D of the red sub-pixel PR can be made larger than the distance D of the green sub-pixel PG.

The pixel electrode 40 is provided on the optical path adjustment layer 34. The pixel electrode 40 is provided between the optical path adjustment layer 34 and the organic layer 42. The pixel electrode 40 is individually provided in a plurality of the light-emitting elements 20. The pixel electrode 40 overlaps the reflection layer 30 in plan view. The pixel electrode 40 transmits the light generated in the light-emitting layer 43. A material of the pixel electrode 40 is, for example, indium tin oxide (ITO) or indium zinc oxide (IZO).

The pixel electrode 40 is electrically coupled to the reflection layer 30 via the contact electrode 41. The pixel electrode 40 is electrically coupled to the pixel circuit 15 by the contact electrode 41 and the reflection layer 30. The material of the contact electrode 41 is, for example, tungsten (W), titanium (Ti), or titanium nitride (TiN). An insulation layer 35 is provided between the contact electrode 41 and the insulation layer 32. The insulation layer 35 is, for example, a silicon oxide layer, a silicon nitride layer, or a silicon oxynitride layer.

The element isolation layer 36 is provided on the pixel electrode 40. The element isolation layer 36 is, for example, a silicon oxide layer, a silicon nitride layer, or a silicon oxynitride layer. An opening 37 is formed in the element isolation layer 36. The opening 37 extends through the element isolation layer 36. The opening 37 defines the light-emitting region 22 of the light-emitting element 20. The light-emitting region 22 is a region where the pixel electrode 40 and the organic layer 42 are in contact with each other. In the example illustrated in FIG. 3, the light-emitting region 22 is a regular octagon, but the shape thereof is not particularly limited.

As illustrated in FIG. 4, the organic layer 42 is provided on the pixel electrode 40. The organic layer 42 is, for example, a layer common to a plurality of the light-emitting elements 20. The organic layer 42 is provided between the pixel electrode 40 and the common electrode 44. The organic layer 42 includes a light-emitting layer 43 made of an organic light-emitting material. The organic light-emitting material forming the light-emitting layer 43 is a luminescent organic compound.

In addition to the light-emitting layer 43, the organic layer 42 includes, for example, a hole injection layer, a hole transport layer, an electron transport layer, and an electron injection layer. The organic layer 42 includes, for example, the light-emitting layer 43 from which red light, green light, and blue light can be obtained, and generates white light emission.

The common electrode 44 is provided on the organic layer 42. The common electrode 44 is provided between the organic layer 42 and the sealing layer 50. The common electrode 44 is, for example, an electrode common to a plurality of the light-emitting elements 20. The material of the common electrode 44 is, for example, an alloy containing Ag, such as MgAg.

The light-emitting element 20 includes an optical resonance portion 24 for reflecting and resonating light in a predetermined wavelength range between the common electrode 44 and the reflection layer 30. The optical resonance portion 24 causes multiple reflections of light generated in the light-emitting layer 43 between the reflection layer 30 and the common electrode 44 to selectively intensify the light in a predetermined wavelength range. The first light-emitting element 20R includes an optical resonance portion 24 that intensifies red light. Each of the light-emitting elements 20G1 and 20G2 includes the optical resonance portion 24 that intensifies green light. The fourth light-emitting element 20B includes the optical resonance portion 24 that intensifies blue light.

The resonance wavelength of the optical resonance portion 24 of the light-emitting element 20 is determined by the distance D. When the resonance wavelength is λ, a relationship of Equation (1) below is established. In Equation (1), n is obtained by calculating and adding an optical path length to the refractive index of each layer between the reflection layer 30 and the common electrode 44. m is a resonance order and is an integer of zero or more. Furthermore, a phase shift due to the reflection by the common electrode 44 is λ/2 in terms of wavelength.

2nD=(m+½)λ (1)

The distance D is set such that the peak wavelength of the light in the wavelength range to be extracted becomes a wavelength A. By setting the distance D, the light in a predetermined wavelength range to be extracted is enhanced, and it is possible to increase the intensity of the light and decrease the spectrum width.

In the example illustrated in FIG. 4, as described above, the distance D is adjusted by making the thicknesses of the optical path adjustment layers 34 different for each of the light-emitting elements 20R, 20G, and 20B. The adjustment method of the distance D is not limited to the adjustment method based on the thickness of the optical path adjustment layer 34. For example, the distance D may be adjusted by making the thicknesses of the pixel electrodes 40 different in the light-emitting elements 20R, 20G, and 20B.

Although not illustrated, the first light-emitting element 20R, the second light-emitting element 20G1, the third light-emitting element 20G2, and the fourth light-emitting element 20B may respectively include the common optical resonance portions 24 having the same distance D. In this case, in the optical resonance portions 24 of the light-emitting elements 20R, 20G, and 20B, light in a common wavelength range is enhanced. In this case, light other than the light in a predetermined wavelength range is attenuated in the colored portion 60. With such a common optical resonance portion 24, it is possible to simplify manufacturing of the display device 100. However, in order to improve the color purity, the light-emitting elements 20R, 20G, and 20B may include optical resonance portions 24 having different distances D, respectively.

The sealing layer 50 is provided on a plurality of the light-emitting elements 20. The sealing layer 50 is provided between a plurality of the light-emitting elements 20 and the colored portion 60. In the illustrated example, the sealing layer 50 is provided on the common electrode 44. The sealing layer 50 covers a plurality of the light-emitting elements 20. The sealing layer 50 transmits light from the light-emitting element 20. The sealing layer 50 has insulating properties.

The sealing layer 50 protects the light-emitting element 20. Specifically, the sealing layer 50 seals the light-emitting element 20 in order to protect the light-emitting element 20 from the outside. The sealing layer 50 has, for example, gas barrier properties. The sealing layer 50 protects the light-emitting element 20 from external moisture, oxygen, and the like. The sealing layer 50 can reduce deterioration of the light-emitting element 20. Therefore, the quality reliability of the display device 100 can be increased.

The sealing layer 50 includes, for example, a first layer 52, a second layer 54, and a third layer 56. The first layer 52 is provided on the light-emitting element 20. The first layer 52 is provided between the light-emitting element 20 and the second layer 54. The second layer 54 is provided on the first layer 52. The second layer 54 is provided between the first layer 52 and the third layer 56. The third layer 56 is provided on the second layer 54. The third layer 56 is provided between the second layer 54 and the colored portion 60.

The material of the first layer 52 and the third layer 56 of the sealing layer 50 is, for example, an inorganic compound such as silicon nitride or silicon oxynitride. The third layer 56 may include an inorganic compound and have an upper surface made of a resin. The second layer 54 is a planarization layer for providing a flat surface to the third layer 56. The material of the second layer 54 is, for example, a resin such as an epoxy resin. Furthermore, the sealing layer 50 may include an adhesive layer for improving adhesion with the colored portion 60 on the side in contact with the colored portion 60. The material of the adhesive layer is, for example, a resin such as an acrylic resin or an epoxy resin.

### 1.2. Colored Portion

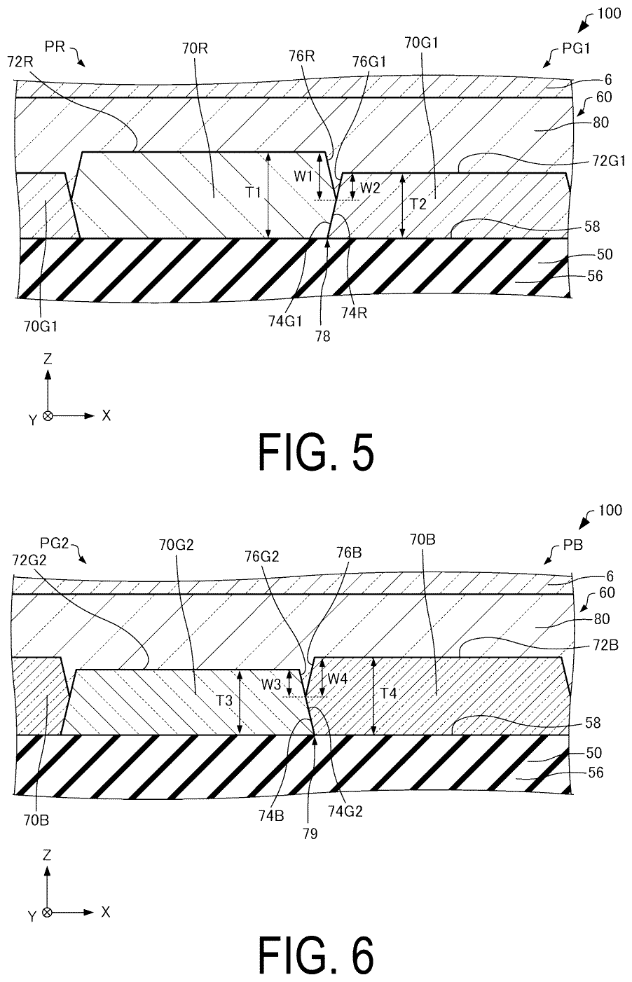

The colored portion 60 is provided on the sealing layer 50. The colored portion 60 is provided between the sealing layer 50 and the light-transmitting substrate 4. For the sake of convenience, FIG. 4 illustrates the colored portion 60 in a simplified manner. Here, FIG. 5 is a cross-sectional view taken along line V-V of FIG. 4, schematically illustrating the display device 100, and a view in the vicinity of the colored portion 60. FIG. 6 is a cross-sectional view taken along line VI-VI of FIG. 4, schematically illustrating the display device 100, and a view in the vicinity of the colored portion 60.

As illustrated in FIGS. 5 and 6, the colored portion 60 includes, for example, a red colored layer 70R, a green colored layer 70G, a blue colored layer 70B, and a light-transmitting layer 80. Colors of the colored layers 70R, 70G, and 70B are different from each other. In the illustrated example, the colored portion 60 includes two green colored layers 70G1 and 70G2 as the green colored layer 70G. The red sub-pixel PR includes the red colored layer 70R. The green sub-pixel PG1 includes the green colored layer 70G1. The green sub-pixel PG2 includes the green colored layer 70G2. The blue sub-pixel PB includes the blue colored layer 70B.

The colored layers 70R, 70G1, 70G2, and 70B are provided on the sealing layer 50. The colored layers 70R, 70G1, 70G2, and 70B are provided between the sealing layer 50 and the light-transmitting layer 80. In the illustrated example, the colored layers 70R, 70G1, 70G2, and 70B are provided on the third layer 56 of the sealing layer 50.

The colored layers 70R, 70G1, 70G2, and 70B are color filters that selectively transmit light in a predetermined wavelength range. The predetermined wavelength range includes the peak wavelength λ determined by the distance D described above. The colored layers 70R, 70G1, 70G2, and 70B are made of, for example, a resin material such as an acrylic photosensitive resin material containing a coloring material. The coloring material is, for example, a pigment or a dye. The colored layers 70R, 70G1, 70G2, and 70B may be a positive color resist.

The red colored layer 70R is provided at the opposite side of the first light-emitting element 20R with respect to the sealing layer 50. The red colored layer 70R overlaps the light-emitting region 22 of the first light-emitting element 20R in plan view. The light from the first light-emitting element 20R passes through the red colored layer 70R. The red colored layer 70R is a color filter that selectively transmits red light out of the light from the first light-emitting element 20R.

As illustrated in FIG. 5, the red colored layer 70R includes a first flat surface 72R, a first side surface 74R, and a first coupling surface 76R.

The first flat surface 72R is a surface at the opposite side of the sealing layer 50. The first flat surface 72R is a flat surface. In the illustrated example, the first flat surface 72R is parallel to the upper surface 58 of the sealing layer 50. The upper surface 58 is a flat surface.

The first side surface 74R is coupled to the upper surface 58. In the illustrated example, the first side surface 74R is inclined with respect to the upper surface 58. The first side surface 74R is in contact with the green colored layer 70G1.

The first coupling surface 76R couples the first flat surface 72R and the first side surface 74R. The first coupling surface 76R is inclined with respect to the first flat surface 72R. The first coupling surface 76R is separated from the green colored layer 70G1. The first coupling surface 76R has a flat surface. The first coupling surface 76R is, for example, a flat surface. In plan view, the first coupling surface 76R overlaps the green colored layer 70G1.

The size W1 of the first coupling surface 76R in the Z-axis direction is, for example, ⅓ or more and ¾ or less of the thickness T1 of the red colored layer 70R. The thickness T1 is the maximum size of the red colored layer 70R in the Z-axis direction. The light from the first light-emitting element 20R is incident on the first flat surface 72R and the first coupling surface 76R.

The green colored layer 70G1 is provided at the opposite side of the second light-emitting element 20G1 with respect to the sealing layer 50. The green colored layer 70G1 overlaps the light-emitting region 22 of the second light-emitting element 20G1 in plan view. The light from the second light-emitting element 20G1 passes through the green colored layer 70G1. The green colored layer 70G1 is a color filter that selectively transmits green light out of the light from the second light-emitting element 20G1.

The green colored layer 70G1 has a tapered shape. In the illustrated example, the shape of the green colored layer 70G1 is a trapezoidal shape. The green colored layer 70G1 includes a second flat surface 72G1, a second side surface 74G1, and a second coupling surface 76G1.

The second flat surface 72G1 is a surface at the opposite side of the sealing layer 50. The second flat surface 72G1 is a flat surface. In the illustrated example, the second flat surface 72G1 is parallel to the upper surface 58 of the sealing layer 50.

The second side surface 74G1 is coupled to the upper surface 58. In the illustrated example, the second side surface 74G1 is inclined with respect to the upper surface 58. The second side surface 74G1 is in contact with the first side surface 74R of the red colored layer 70R.

The second coupling surface 76G1 couples the second flat surface 72G1 and the second side surface 74G1. The second coupling surface 76G1 is inclined with respect to the second flat surface 72G1. The second coupling surface 76G1 is separated from the red colored layer 70R. The second coupling surface 76G1 has a flat surface. The second coupling surface 76G1 is, for example, a flat surface.

The size W2 of the second coupling surface 76G1 in the Z-axis direction is, for example, ⅓ or more and ¾ or less of the thickness T2 of the green colored layer 70G1. The thickness T2 is the maximum size of the green colored layer 70G1 in the Z-axis direction. In the illustrated example, the thickness T2 is smaller than the thicknesses T1. For example, the size W1 and the size W2 are different from each other. In the illustrated example, the size W2 is smaller than the size W1. The light from the second light-emitting element 20G1 is incident on the second flat surface 72G1 and the second coupling surface 76G1.

A contact portion 78 between the first side surface 74R and the second side surface 74G1 is in contact with the sealing layer 50. The contact portion 78 is coupled to the upper surface 58. In the illustrated example, the contact portion 78 is inclined with respect to the upper surface 58. The entire surface of the first side surface 74R is in contact with the second side surface 74G1. The entire surface of the second side surface 74G1 is in contact with the first side surface 74R.

As illustrated in FIG. 6, the green colored layer 70G2 is provided at the opposite side of the third light-emitting element 20G2 with respect to the sealing layer 50. The green colored layer 70G2 overlaps the light-emitting region 22 of the third light-emitting element 20G2 in plan view. The light from the third light-emitting element 20G2 passes through the green colored layer 70G2. The green colored layer 70G2 is a color filter that selectively transmits green light out of the light from the third light-emitting element 20G2.

The green colored layer 70G2 has a tapered shape. In the illustrated example, the shape of the green colored layer 70G2 is a trapezoidal shape. The green colored layer 70G2 includes a third flat surface 72G2, a third side surface 74G2, and a third coupling surface 76G2.

The third flat surface 72G2 is a surface at the opposite side of the sealing layer 50. The third flat surface 72G2 is a flat surface. In the illustrated example, the third flat surface 72G2 is parallel to the upper surface 58 of the sealing layer 50.

The third side surface 74G2 is coupled to the upper surface 58. In the illustrated example, the third side surface 74G2 is inclined with respect to the upper surface 58. The third side surface 74G2 is in contact with the blue colored layer 70B.

The third coupling surface 76G2 couples the third flat surface 72G2 and the third side surface 74G2. The third coupling surface 76G2 is inclined with respect to the third flat surface 72G2. The third coupling surface 76G2 is separated from the blue colored layer 70B. The third coupling surface 76G2 has a flat surface. The third coupling surface 76G2 is, for example, a flat surface.

The size W3 of the third coupling surface 76G2 in the Z-axis direction is, for example, ⅓ or more and ¾ or less of the thickness T3 of the green colored layer 70G2. The thickness T3 is the maximum size of the green colored layer 70G2 in the Z-axis direction. The light from the third light-emitting element 20G2 is incident on the third flat surface 72G2 and the third coupling surface 76G2.

The blue colored layer 70B is provided at the opposite side of the fourth light-emitting element 20B with respect to the sealing layer 50. The blue colored layer 70B overlaps the light-emitting region 22 of the fourth light-emitting element 20B in plan view. The blue colored layer 70B is a color filter that selectively transmits blue light out of the light from the fourth light-emitting element 20B.

The blue colored layer 70B includes a fourth flat surface 72B, a fourth side surface 74B, and a fourth coupling surface 76B.

The fourth flat surface 72B is a surface at the opposite side of the sealing layer 50. The fourth flat surface 72B is a flat surface. In the illustrated example, the fourth flat surface 72B is parallel to the upper surface 58 of the sealing layer 50.

The fourth side surface 74B is coupled to the upper surface 58. In the illustrated example, the fourth side surface 74B is inclined with respect to the upper surface 58. The fourth side surface 74B is in contact with the third side surface 74G2 of the green colored layer 70G2.

The fourth coupling surface 76B couples the fourth flat surface 72B and the fourth side surface 74B. The fourth coupling surface 76B is inclined with respect to the fourth flat surface 72B. The fourth coupling surface 76B is separated from the green colored layer 70G2. The fourth coupling surface 76B has a flat surface. The fourth coupling surface 76B is, for example, a flat surface. In plan view, the fourth coupling surface 76B overlaps the green colored layer 70G2.

The size W4 of the fourth coupling surface 76B in the Z-axis direction is, for example, ⅓ or more and ¾ or less of the thickness T4 of the blue colored layer 70B. The thickness T4 is the maximum size of the blue colored layer 70B in the Z-axis direction. In the illustrated example, the thickness T4 is larger than the thicknesses T3. For example, the size W3 and the size W4 are different from each other. In the illustrated example, the size W4 is larger than the size W3. The light from the fourth light-emitting element 20B is incident on the fourth flat surface 72B and the fourth coupling surface 76B.

A contact portion 79 between the third side surface 74G2 and the fourth side surface 74B is in contact with the sealing layer 50. The contact portion 79 is coupled to the upper surface 58. In the illustrated example, the contact portion 79 is inclined with respect to the upper surface 58. The entire surface of the third side surface 74G2 is in contact with the fourth side surface 74B. The entire surface of the fourth side surface 74B is in contact with the third side surface 74G2.

As illustrated in FIGS. 5 and 6, the light-transmitting layer 80 is provided on the colored layers 70R, 70G1, 70G2, and 70B. The light-transmitting layer 80 is provided between the colored layers 70R, 70G1, 70G2, and 70B and the adhesive layer 6. The light-transmitting layer 80 covers the colored layers 70R, 70G1, 70G2, and 70B. Specifically, the light-transmitting layer 80 covers the flat surfaces 72R, 72G1, 72G2, and 72B and the coupling surfaces 76R, 76G1, 76G2, and 76B. The upper surface of the light-transmitting layer 80 is, for example, a flat surface. The light-transmitting layer 80 covers the colored layers 70R, 70G1, 70G2, and 70B.

The light-transmitting layer 80 transmits light from the light-emitting element 20. The light-transmitting layer 80 is, for example, a silicon oxide layer, a silicon nitride layer, or a silicon oxynitride layer. The refractive index of the light-transmitting layer 80 is different from the refractive indexes of the colored layers 70R, 70G1, 70G2, and 70B. The refractive indexes of the colored layers 70R, 70G1, 70G2, and 70B can be adjusted by additives or the like.

The refractive index of the light-transmitting layer 80 may be higher than the refractive indexes of the colored layers 70R, 70G1, 70G2, and 70B. In this case, the difference between the refraction index of the light-transmitting layer 80 and the refractive indexes of the colored layers 70R, 70G1, 70G2, and 70B may be 0.2 or more. The colored layers 70R, 70G1, 70G2, and 70B condense light from the light-emitting element 20 at the coupling surfaces 76R, 76G1, 76G2, and 76B, respectively. Thus, the light extraction efficiency can be improved.

The refractive index of the light-transmitting layer 80 may be lower than the refractive indexes of the colored layers 70R, 70G1, 70G2, and 70B. In this case, the difference between the refraction index of the light-transmitting layer 80 and the refractive indexes of the colored layers 70R, 70G1, 70G2, and 70B may be 0.1 or more. The colored layers 70R, 70G1, 70G2, and 70B diverge light from the light-emitting element 20 at the coupling surfaces 76R, 76G1, 76G2, and 76B, respectively. Thus, a viewing angle characteristic can be improved. The colored layers 70R, 70G1, 70G2, and 70B have a function as lenses by using the coupling surfaces 76R, 76G1, 76G2, and 76B.

Although not illustrated, for example, the red colored layer 70R includes a side surface in contact with the green colored layer 70G2 and a coupling surface coupling the side surface and the first flat surface 72R and separated from the green colored layer 70G2. The green colored layer 70G1 includes a side surface in contact with the red colored layer 70R, and a coupling surface coupling the side surface and the third flat surface 72G2 and separated from the red colored layer 70R. The contact portion between the side surface of the red colored layer 70R and the side surface of the green colored layer 70G2 is in contact with the sealing layer 50.

Moreover, the above description is also applied to, for example, the green colored layer 70G2 and the blue colored layer 70B. Furthermore, the above description is also applied to, for example, a colored layer and a colored layer that constitutes a pixel P adjacent to the pixel P including the colored layer and is adjacent to the colored layer. That is, the above description is applied to adjacent colored layers among a plurality of the colored layers.

### 1.3. Effects

The display device 100 includes the substrate 10, the first light-emitting element 20R and second light-emitting element 20G1 provided at the substrate 10, and the sealing layer 50 covering the first light-emitting element 20R and the second light-emitting element 20G1. Moreover, the display device 100 includes the red colored layer 70R as the first colored layer which is provided at the opposite side of the first light-emitting element 20R with respect to the sealing layer 50 and through which the light from the first light-emitting element 20R passes. Moreover, the display device 100 includes the green colored layer 70G1 as the second colored layer which is provided at the opposite side of the second light-emitting element 20G1 with respect to the sealing layer 50 and through which the light from the second light-emitting element 20G1 passes. The red colored layer 70R includes the first flat surface 72R at the opposite side of the sealing layer 50, the first side surface 74R in contact with the green colored layer 70G1, and the first coupling surface 76R which is inclined with respect to the first flat surface 72R, couples the first flat surface 72R and the first side surface 74R, and is separated from the green colored layer 70G1. The green colored layer 70G1 includes the second flat surface 72G1 at the opposite side of the sealing layer 50, the second side surface 74G1 in contact with the first side surface 74R, and the second coupling surface 76G1 which is inclined with respect to the second flat surface 72G1, couples the second flat surface 72G1 and the second side surface 74G1, and is separated from the red colored layer 70R. The contact portion 78 between the first side surface 74R and the second side surface 74G1 is in contact with the sealing layer 50.

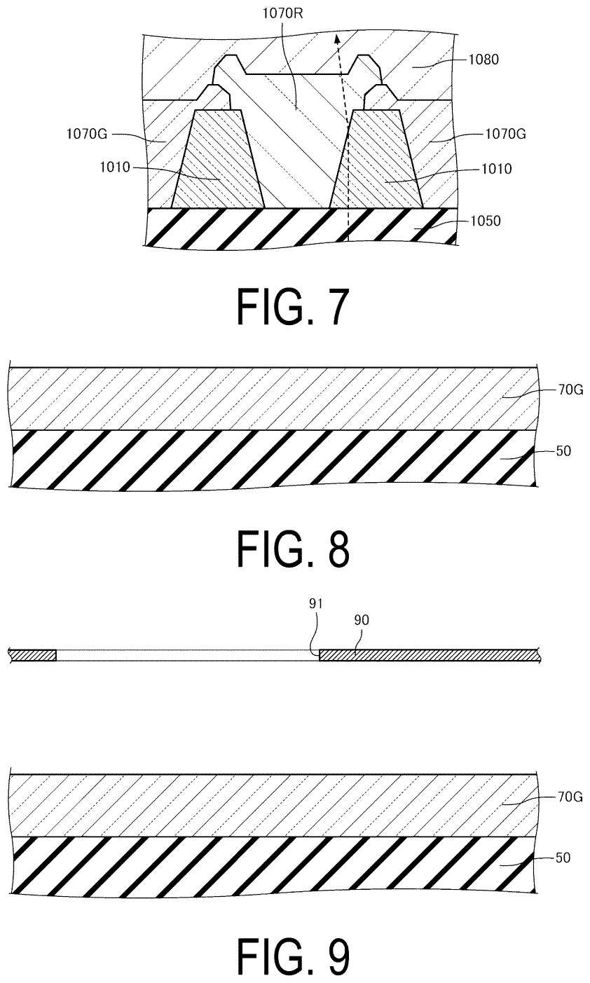

Therefore, in display device 100, the color purity can be improved. For example, as illustrated in FIG. 7, when a wall portion 1010 is provided between a red colored layer 1070R and a green colored layer 1070G and on a sealing layer 1050, there is light incident on the wall portion 1010 before the light is incident on the red colored layer 1070R as indicated by a dashed arrow illustrated in FIG. 7. In particular, when the pixel size is reduced, there is a limit in reducing the size of the wall portion 1010, and thus the proportion occupied by the wall portion 1010 with respect to the red colored layer 1070R is increased. Therefore, the proportion of the light incident on the wall portion 1010 is increased before the light is incident on the red colored layer 1070R. Since the distance of the light passing through the red colored layer 1070R is shortened, the purity of red color is reduced. A light-transmitting layer 1080 is provided on the colored layers 1070R and 1070G.

On the other hand, in the display device 100, the contact portion 78 between the first side surface 74R and the second side surface 74G1 is in contact with the sealing layer 50. Thus, there is no wall portion in contact with the sealing layer 50 between the red colored layer 70R and the green colored layer 70G1. Therefore, even when the size of the pixel P is reduced, the color purity is unlikely to decrease. Therefore, the color purity can be improved. FIG. 7 is a cross-sectional view schematically illustrating a display device according to a reference example.

The display device 100 includes the light-transmitting layer 80 covering the first flat surface 72R, the first coupling surface 76R, the second flat surface 72G1, and the second coupling surface 76G1, and the refractive index of the light-transmitting layer 80 is different from the refractive index of the red colored layer 70R and the refractive index of the green colored layer 70G1. Therefore, in the display device 100, the red colored layer 70R can have a function as a lens with the first coupling surface 76R. Moreover, the green colored layer 70G1 can have a function as a lens with the second coupling surface 76G1.

In the display device 100, the first coupling surface 76R and the second coupling surface 76G1 have flat surfaces. Therefore, in the display device 100, the light from the first light-emitting element 20R can be refracted by the first coupling surface 76R having a flat surface. Moreover, the light from the second light-emitting element 20G1 can be refracted by the second coupling surface 76G1 having a flat surface.

In the display device 100, the size W1 of the substrate 10 of the first coupling surface 76R in a direction of a vertical line Q of the substrate 10 is, for example, ⅓ or more of the thickness T1 of the red colored layer 70R. Therefore, in the display device 100, the red colored layer 70R can have a sufficient function as a lens with the first coupling surface 76R.

In the display device 100, the size W2 of the second coupling surface 76G1 in the direction of the vertical line Q is, for example, ⅓ or more of the thickness T2 of the green colored layer 70G1. Therefore, in the display device 100, the green colored layer 70G1 can have a sufficient function as a lens with the second coupling surface 76G1.

In display device 100, the size W1 of the first coupling surface 76R in the direction of the vertical line Q and the size W2 of the second coupling surface 76G1 in the direction of the vertical line Q are different from each other. Therefore, in the display device 100, the functions as the lenses can be changed by the red colored layer 70R and the green colored layer 70G1.

The display device 100 includes the third light-emitting element 20G2 and the fourth light-emitting element 20B, which are provided at the substrate 10 and covered with the sealing layer 50. Moreover, the display device 100 includes the green colored layer 70G2 as a third colored layer which is provided at the opposite side of the third light-emitting element 20G2 with respect to the sealing layer 50 and through which the light from the third light-emitting element 20G2 passes. Moreover, the display device 100 includes the blue colored layer 70B as a fourth colored layer which is provided at the opposite side of the fourth light-emitting element 20B with respect to the sealing layer 50 and through which the light from the fourth light-emitting element 20B passes. The green colored layer 70G2 includes the third flat surface 72G2 at the opposite side of the sealing layer 50, the third side surface 74G2 in contact with the blue colored layer 70B, and the third coupling surface 76G2 which is inclined with respect to the third flat surface 72G2, couples the third flat surface 72G2 and the third side surface 74G2, and is separated from the blue colored layer 70B. The blue colored layer 70B includes the fourth flat surface 72B at the opposite side of the sealing layer 50, the fourth side surface 74B in contact with the third side surface 74G2, and the fourth coupling surface 76B which is inclined with respect to the fourth flat surface 72B, couples the fourth flat surface 72B and the fourth side surface 74B, and is separated from the green colored layer 70G2. The contact portion 79 between the third side surface 74G2 and the fourth side surface 74B is in contact with the sealing layer 50. The size W3 of the third coupling surface 76G2 in the direction of the vertical line Q and the size W4 of the fourth coupling surface 76B in the direction of the vertical line Q are different from each other. Therefore, in the display device 100, the functions as the lenses can be changed by the green colored layer 70G2 and the blue colored layer 70B.

### 2. Method for Manufacturing Display Device

Next, a method for manufacturing the display device 100 according to the present embodiment will be described with reference to the drawings. FIGS. 8 to 13 are cross-sectional views schematically illustrating manufacturing steps of the display device 100 according to the present embodiment.

As illustrated in FIG. 8, the green colored layer 70G is applied on the sealing layer 50. The green colored layer 70G is applied by, for example, a spin coating method. The green colored layer 70G is, for example, a color resist. Next, the green colored layer 70G is prebaked.

As illustrated in FIG. 9, the green colored layer 70G is exposed by using a mask layer 90 as a mask. An opening 91 is formed at the mask layer 90.

As illustrated in FIG. 10, the exposed green colored layer 70G is developed. Next, the green colored layer 70G is post-baked. As a result, the green colored layer 70G having a predetermined shape can be formed.

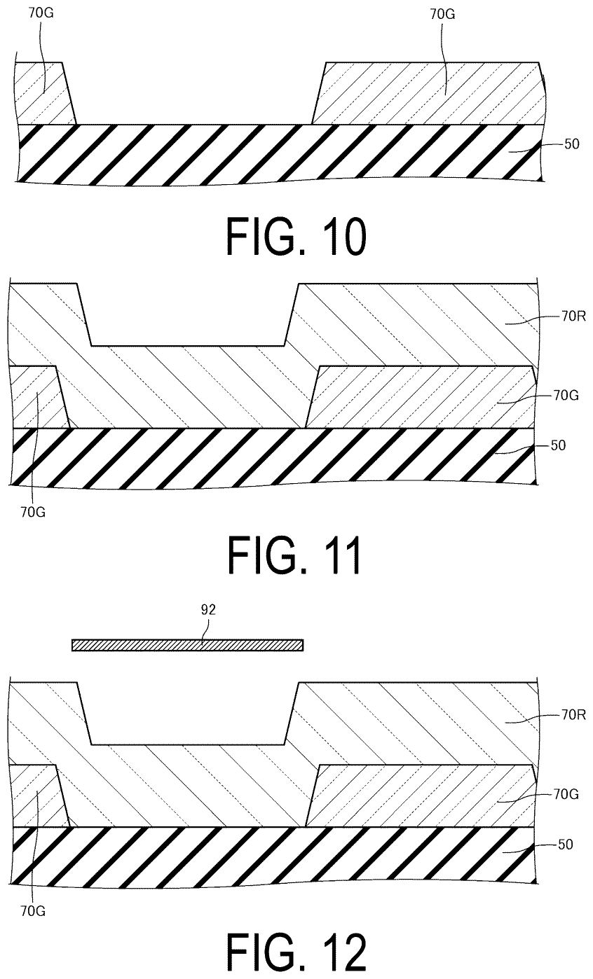

As illustrated in FIG. 11, the red colored layer 70R is applied on the sealing layer 50 and the green colored layer 70G. The red colored layer 70R is applied by, for example, a spin coating method. The red colored layer 70R is, for example, a color resist. Next, the red colored layer 70R is prebaked.

As illustrated in FIG. 12, the red colored layer 70R is exposed by using a mask layer 92 as a mask. In plan view, for example, the mask layer 92 overlaps the green colored layer 70G. The mask layer 92 may overlap a part of the green colored layer 70G in plan view.

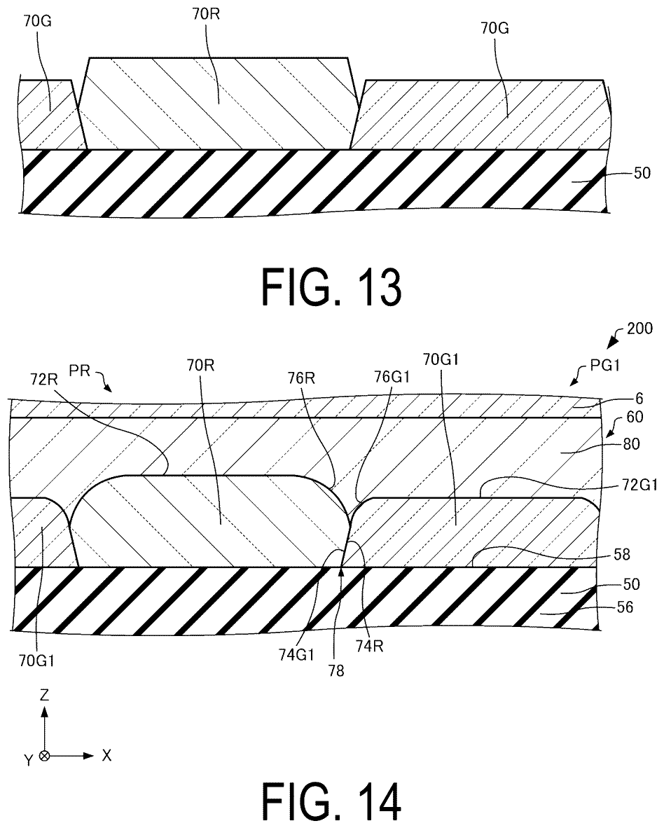

As illustrated in FIG. 13, the exposed red colored layer 70R is developed. Next, the red colored layer 70R is post-baked. Thus, the red colored layer 70R having a predetermined shape can be formed.

Next, for example, the blue colored layer 70B is formed in the same manner as the red colored layer 70R. The order of forming the colored layers 70R, 70G, and 70B is not particularly limited. For example, the blue colored layer 70B may be formed before the red colored layer 70R is formed.

As illustrated in FIGS. 5 and 6, the light-transmitting layer 80 is formed on the colored layers 70R, 70G, and 70B. The light-transmitting layer 80 is formed by, for example, a chemical vapor deposition (CVD) method.

As illustrated in FIG. 4, the light-transmitting substrate 4 is bonded to the element substrate 2 via the adhesive layer 6.

With the steps described above, the display device 100 can be manufactured. For example, the element substrate 2 is manufactured by using a semiconductor manufacturing process.

### 3. Modification Example of Display Device

### 3.1. First Modification Example

Next, a display device according to a first modification example of the present embodiment will be described with reference to the drawings. FIG. 14 is a cross-sectional view schematically illustrating a display device 200 according to the first modification example of the present embodiment.

Hereinafter, in the display device 200 according to the first modification example of the present embodiment, members having the same functions as the constituent members of the display device 100 according to the present embodiment described above will be denoted by the same reference signs, and detailed description thereof will be omitted. This also applies to display devices according to second to fourth modification examples of the present embodiment, which will be described later.

In the display device 100 described above, as illustrated in FIG. 5, the first coupling surface 76R and the second coupling surface 76G1 have flat surfaces.

On the other hand, in the display device 200, as illustrated in FIG. 14, the first coupling surface 76R and the second coupling surface 76G1 have curved surfaces. The first coupling surface 76R and the second coupling surface 76G1 are, for example, curved surfaces.

Although not illustrated, the shapes of the first coupling surface 76R and the second coupling surface 76G1 are not particularly limited. For example, protrusions may be provided at the coupling surfaces 76R and 76G1. Furthermore, although not illustrated, the third coupling surface 76G2 of the green colored layer 70G1 and the fourth coupling surface 76B of the blue colored layer 70B may have curved surfaces.

In the display device 200, the first coupling surface 76R and the second coupling surface 76G1 have curved surfaces. Therefore, in the display device 200, the light from the first light-emitting element 20R can be refracted by the first coupling surface 76R having a curved surface. Moreover, the light from the second light-emitting element 20G1 can be refracted by the second coupling surface 76G1 having a curved surface.

### 3.2. Second Modification Example

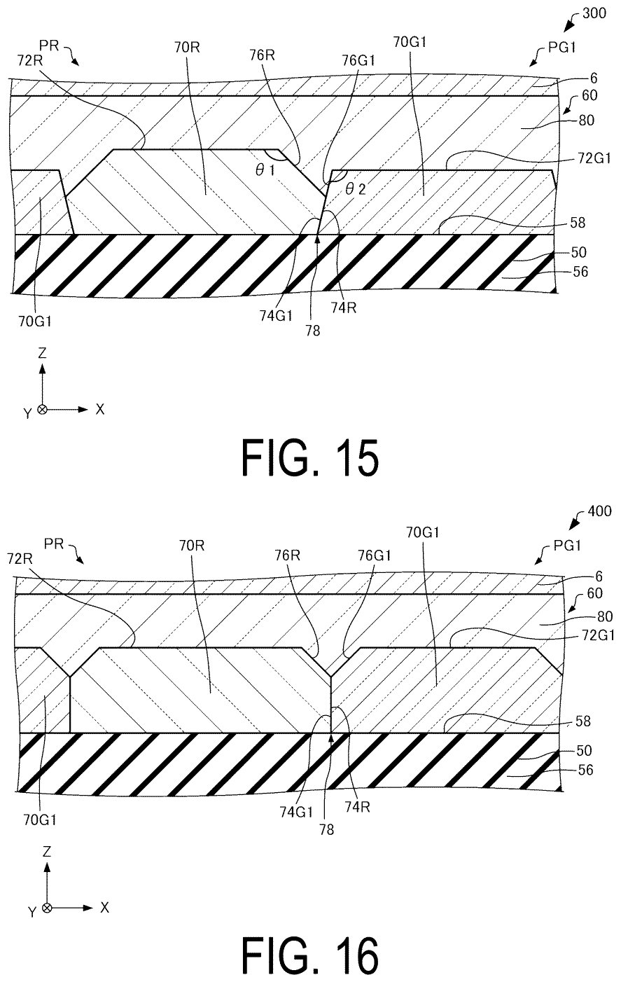

Next, a display device according to a second modification example of the present embodiment will be described with reference to the drawings. FIG. 15 is a cross-sectional view schematically illustrating a display device 300 according to the second modification example of the present embodiment.

In the display device 100 described above, as illustrated in FIG. 5, an angle formed by the first flat surface 72R and the first coupling surface 76R is the same as an angle formed by the second flat surface 72G1 and the second coupling surface 76G1.

On the other hand, in the display device 300, as illustrated in FIG. 15, an angle θ1 formed by the first flat surface 72R and the first coupling surface 76R is different from an angle θ2 formed by the second flat surface 72G1 and the second coupling surface 76G1. In the illustrated example, the angle θ1 is larger than the angle θ2. The angle θ1 and the angle θ2 may be obtuse angles. The angle θ2 may be a right angle. For example, the angle θ1 and the angle θ2 can be adjusted by adjusting conditions for the post-baking of the red colored layer 70R and the post-baking of the green colored layer 70G1. Furthermore, when a positive color resist is used as the colored layers 70R and 70G1, the angles θ1 and 02 tend to increase.

Although not illustrated, the angle formed by the third flat surface 72G2 of the green colored layer 70G1 and the third coupling surface 76G2 may be different from the angle formed by the fourth flat surface 72B of the blue colored layer 70B and the fourth coupling surface 76B.

In the display device 200, the angle θ1 formed by the first flat surface 72R and the first coupling surface 76R is different from the angle θ2 formed by the second flat surface 72G1 and the second coupling surface 76G1. Therefore, the refraction angle of the light from the first light-emitting element 20R at the first coupling surface 76R and the refraction angle of the light from the second light-emitting element 20G1 at the second coupling surface 76G1 can be changed. For example, when the area of the light-emitting region 22 of the first light-emitting element 20R is smaller than the area of the light-emitting region 22 of the second light-emitting element 20G1, the light from the first light-emitting element 20R is less likely to diverge. Thus, by making the angle θ1 larger than the angle θ2, the difference in radiation angle between the light emitted from the red sub-pixel PR and the light emitted from the green sub-pixel PG1 can be reduced. Therefore, the color viewing angle characteristic of the display device 300 can be improved.

### 3.3. Third Modification Example

Next, a display device according to a third modification example of the present embodiment will be described with reference to the drawings. FIG. 16 is a cross-sectional view schematically illustrating a display device 400 according to the third modification example of the present embodiment.

In the display device 100 described above, as illustrated in FIG. 5, the contact portion 78 between the first side surface 74R and the second side surface 74G1 is inclined with respect to the upper surface 58 of the sealing layer 50.

On the other hand, in the display device 400, as illustrated in FIG. 16, the contact portion 78 between the first side surface 74R and the second side surface 74G1 is perpendicular to the upper surface 58 of the sealing layer 50. The first side surface 74R and the second side surface 74G1 are perpendicular to the upper surface 58.

Although not illustrated, the contact portion 79 between the third side surface 74G2 of the green colored layer 70G1 and the fourth side surface 74B of the blue colored layer 70B may be perpendicular to the upper surface 58.

### 3.4. Fourth Modification Example

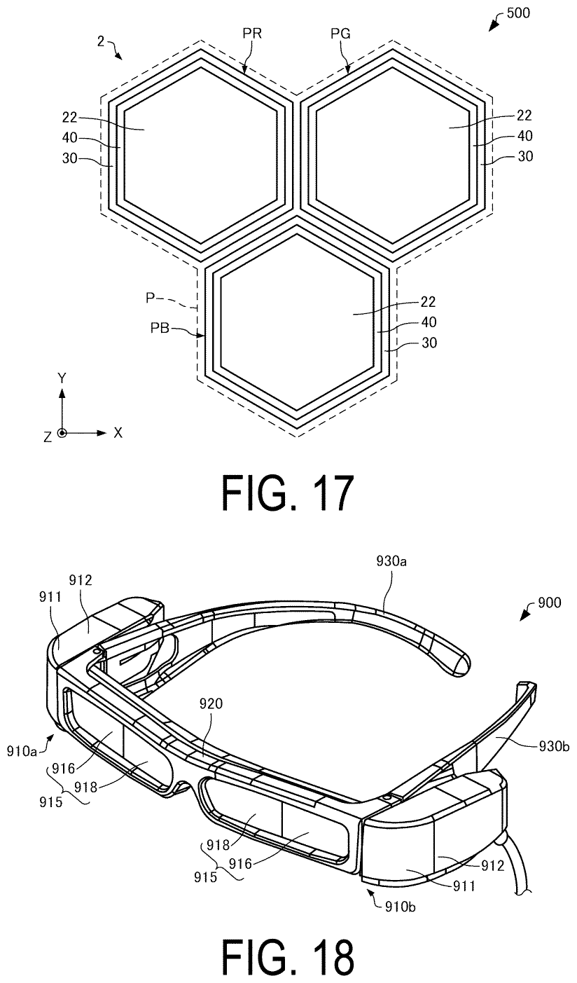

Next, a display device according to a fourth modification example of the present embodiment will be described with reference to the drawings. FIG. 17 is a plan view schematically illustrating a display device 500 according to the fourth modification example of the present embodiment. For the sake of convenience, in FIG. 17, members other than the light-emitting region 22, the reflection layer 30, and the pixel electrode 40 are not illustrated.

In the display device 100 described above, as illustrated in FIG. 3, two green sub-pixels PG are provided as the green sub-pixels PG1 and PG2 in one pixel P.

On the other hand, in the display device 500, as illustrated in FIG. 17, one green sub-pixel PG is provided in one pixel P. For example, the sub-pixels PR, PG, and PB are delta-arranged. In the illustrated example, the shape of the light-emitting region 22 is a regular hexagon.

### 4. Electronic Apparatus

### 4.1. Overall Configuration

Next, a head-mounted display being an electronic apparatus according to the present embodiment is described with reference to the drawings. FIG. 18 is a perspective view schematically illustrating a head-mounted display 900 according to the present embodiment.

As illustrated in FIG. 18, the head-mounted display 900 is a head-mounted display that has an outer appearance of an eyewear. The head-mounted display 900 is mounted on the head of a viewer. The viewer is a user who uses the head-mounted display 900. The head-mounted display 900 allows the viewer to visually recognize image light of a virtual image and to visually recognize an external image in a see-through manner.

For example, the head-mounted display 900 includes a first display unit 910a, a second display unit 910b, a frame 920, a first temple 930a, and a second temple 930b.

The first display unit 910a and the second display unit 910b display images. Specifically, the first display unit 910a displays a virtual image for the right eye of the viewer. The second display unit 910b displays a virtual image for the left eye of the viewer. The display units 910a and 910b include, for example, an image forming device 911 and a light-guide device 915.

The image forming device 911 generates image light. The image forming device 911 includes, for example, an optical system such as a light source and a projection device, and an external member 912. The external member 912 houses the light source and the projection device.

The light-guide device 915 covers the front of the eyes of the viewer. The light-guide device 915 guides the image light formed by the image forming device 911 and allows the viewer to visually recognize external light and the image light in an overlapping manner. Details of the image forming device 911 and the light-guide device 915 will be described below.

The frame 920 supports the first display unit 910a and the second display unit 910b. For example, the frame 920 surrounds the display units 910a and 910b. In the illustrated example, the image forming device 911 of the first display unit 910a is attached to one end portion of the frame 920. The image forming device 911 of the second display unit 910b is attached to the other end portion of the frame 920.

The first temple 930a and the second temple 930b extend from the frame 920. In the illustrated example, the first temple 930a extends from one end portion of the frame 920. The second temple 930b extends from the other end portion of the frame 920.

The first temple 930a and the second temple 930b are put on the ears of the viewer when the head-mounted display 900 is worn by the viewer. The head of the viewer is positioned between the temples 930a and 930b.

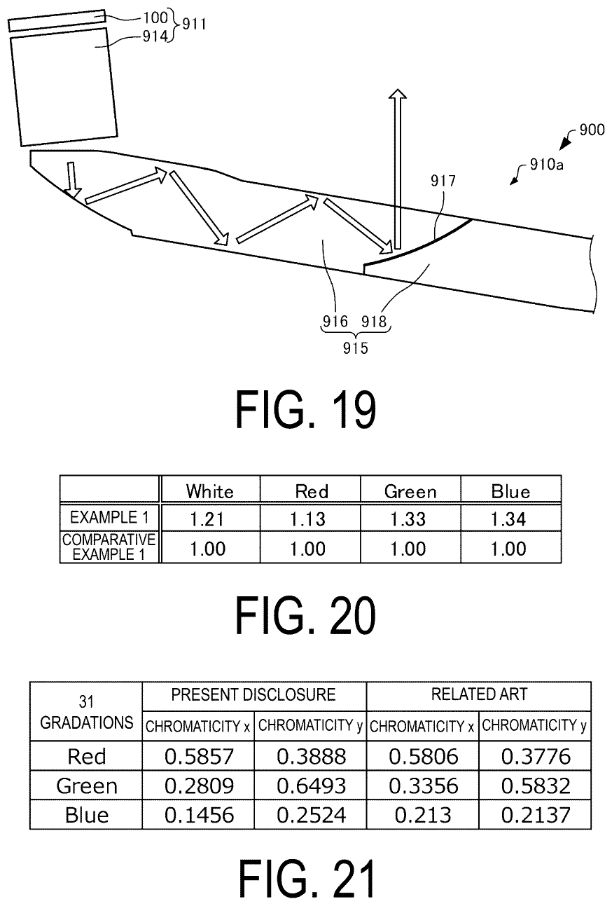

4.2. Image Forming Device and Light-guide Device FIG. 19 is a diagram schematically illustrating the image forming device 911 and the light-guide device 915 of the first display unit 910a of the head-mounted display 900. The first display unit 910a and the second display unit 910b have basically the same configuration. Therefore, the following description on the first display unit 910a is applied to the second display unit 910b.

As illustrated in FIG. 19, for example, the image forming device 911 includes the display device 100 as the light source and a projection device 914 for image formation.

The projection device 914 projects the image light emitted from the display device 100 toward the light-guide device 915. The projection device 914 is, for example, a projection lens. As the lens constituting the projection device 914, a lens having an axially symmetric surface as a lens surface may be used.

For example, the light-guide device 915 is accurately positioned with respect to the projection device 914 by being screwed to a lens barrel of the projection device 914. The light-guide device 915 includes, for example, an image light-guide member 916 that guides the image light and a see-through member 918 for see-through view.

The image light emitted from the projection device 914 is incident on the image light-guide member 916. The image light-guide member 916 is a prism that guides the image light toward the eyes of the viewer. The image light incident on the image light-guide member 916 is repeatedly reflected on the inner surface of the image light-guide member 916, and then is reflected by a reflection layer 917 to be emitted from the image light-guide member 916. The image light emitted from the image light-guide member 916 reaches the eyes of the viewer. The reflection layer 917 is constituted by, for example, metal or a dielectric multilayer film. The reflection layer 917 may be a half mirror.

The see-through member 918 is adjacent to the image light-guide member 916. The see-through member 918 is fixed to the image light-guide member 916. For example, the outer surface of the see-through member 918 is continuous with the outer surface of the image light-guide member 916. The viewer sees the external light through the see-through member 918. The image light-guide member 916 also has a function of making the viewer see the external light therethrough, in addition to the function of guiding the image light. The head-mounted display 900 may be configured so as not to allow the viewer to see the external light therethrough.

The electronic apparatus according to the present embodiment is not limited the head-mounted display as long as the display device according to the present embodiment is included. The electronic apparatus according to the present embodiment may be an electronic view finder (EVF), a projector, a wearable display such as a smart watch, or a vehicle head-up display.

### 5. Examples and Comparative Examples

As Example 1, a display device corresponding to FIGS. 1 to 6 is prepared. In Example 1, the adjacent colored layers are in contact with each other, and the contact portion between the adjacent colored layers is in contact with the sealing layer. As Comparative Example 1, a comparative example corresponding to FIG. 7 is prepared. In Comparative Example 1, the wall portion is provided on the sealing layer, and the wall portion is positioned between the adjacent colored layers.

In Example 1 and Comparative Example 1, the light extraction efficiency is measured. FIG. 20 is a table showing the light extraction efficiency in Example 1 and Comparative Example 1. In FIG. 20, the extraction efficiency of Comparative Example 1 is standardized as “one”. As illustrated in FIG. 20, it is found that the light extraction efficiency of Example 1 is higher than that of Comparative Example 1 for white light, red light, green light, and blue light.

In Example 1 and Comparative Example 1, the color gamut at the time of low-gradation lighting is measured. As a measuring instrument, a spectral radiation luminance meter “CS2000A” manufactured by Konica Minolta is used. The measurement item is “chromaticity x, y”. The measurement method is “radiation”. The measurement speed is “Normal”. The measurement mode is “No-Sync”.

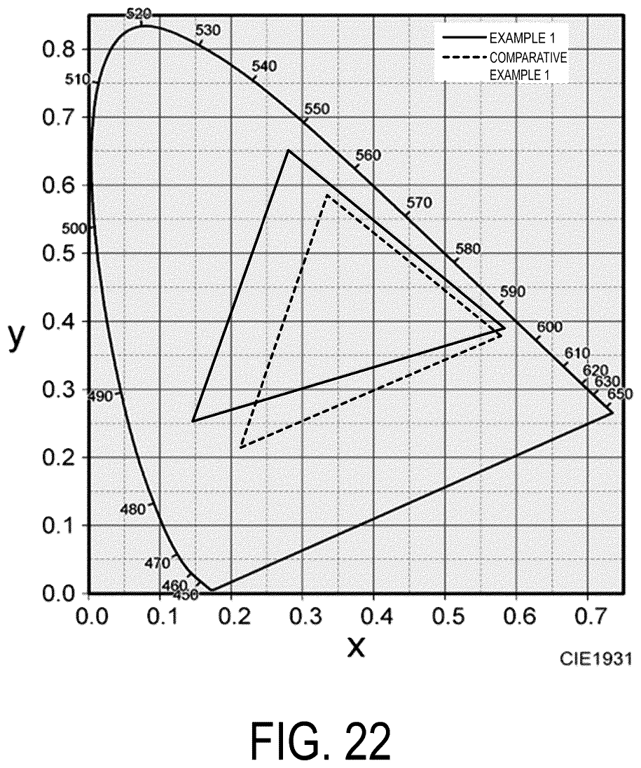

FIG. 21 is a table showing a measurement result of the color gamut in Example 1 and Comparative Example 1. FIG. 22 is a CIE1931 color space showing the measurement result of the color gamut in Example 1 and Comparative Example 1. As illustrated in FIGS. 21 and 22, it is found that Example 1 has a wider color gamut than Comparative Example 1. In general, the color gamut tends to be narrow at the time of low gradation lighting or when the pixel size is small. In such a case, Example 1 can be said to be particularly effective.

The embodiment and the modification example that are described above are merely examples, and are not limited thereto. For example, the embodiment and the modification example can also be combined as appropriate.

The present disclosure includes configurations that are substantially identical to the configurations described in the embodiment, for example, configurations with identical functions, methods, and results, or with identical advantages and effects. Furthermore, the present disclosure includes configurations obtained by replacing non-essential portions of the configurations described in the embodiment. Furthermore, the present disclosure includes configurations having the same operations and effects or can achieve the same advantages as those of the configurations described in the embodiments. Furthermore, the present disclosure includes configurations obtained by adding known techniques to the configurations described in the embodiment.

The following content is derived from the embodiment and the modification example that are described above.

A display device according to an aspect includes: a substrate; a first light-emitting element and a second light-emitting element that are provided at the substrate; a sealing layer covering the first light-emitting element and the second light-emitting element; a first colored layer that is provided at an opposite side of the first light-emitting element with respect to the sealing layer and through which light from the first light-emitting element passes; and a second colored layer that is provided at an opposite side of the second light-emitting element with respect to the sealing layer and through which light from the second light-emitting element passes, in which the first colored layer includes a first flat surface at an opposite side of the sealing layer, a first side surface in contact with the second colored layer, and a first coupling surface inclined with respect to the first flat surface, coupling the first flat surface and the first side surface, and separated from the second colored layer, the second colored layer includes a second flat surface at an opposite side of the sealing layer, a second side surface in contact with the first side surface, and a second coupling surface inclined with respect to the second flat surface, coupling the second flat surface and the second side surface, and separated from the first colored layer, and a contact portion between the first side surface and the second side surface is in contact with the sealing layer.

In this display device, the color purity can be improved.

The display device according to an aspect may further includes a light-transmitting layer covering the first flat surface, the first coupling surface, the second flat surface, and the second coupling surface, in which a refractive index of the light-transmitting layer may be different from a refractive index of the first colored layer and a refractive index of the second colored layer.

In this display device, the first colored layer can have a function as a lens with the first coupling surface. Moreover, the second colored layer can have a function as a lens with the second coupling surface.

In the display device according to an aspect, the first coupling surface and the second coupling surface may have flat surfaces.

In this display device, the light from the first light-emitting element can be refracted by the first coupling surface having the flat surface. Moreover, the light from the second light-emitting element can be refracted by the second coupling surface having the flat surface.

In the display device according to an aspect, an angle formed by the first flat surface and the first coupling surface may be different from an angle formed by the second flat surface and the second coupling surface.

In this display device, the refraction angle of the light from the first light-emitting element at the first coupling surface and the refraction angle of the light from the second light-emitting element at the second coupling surface can be changed.

In the display device according to an aspect, the first coupling surface and the second coupling surface may have curved surfaces.

In this display device, the light from the first light-emitting element can be refracted by the first coupling surface having the curved surface. Moreover, the light from the second light-emitting element can be refracted by the second coupling surface having the curved surface.

In the display device according to an aspect, a size of the first coupling surface in a perpendicular direction to the substrate may be ⅓ or more of a thickness of the first colored layer.

In this display device, the first colored layer can have a sufficient function as a lens with the first coupling surface.

In the display device according to an aspect, a size of the second coupling surface in the perpendicular direction may be ⅓ or more of a thickness of the second colored layer.

In this display device, the second colored layer can have a sufficient function as a lens with the second coupling surface.

In the display device according to an aspect, a size of the first coupling surface in a perpendicular direction to the substrate and a size of the second coupling surface in the perpendicular direction may be different from each other.

In this display device, the function as the lens can be changed by the first colored layer and the second colored layer.

The display device according to an aspect may further includes: a third light-emitting element and a fourth light-emitting element that are provided at the substrate and covered by the sealing layer; a third colored layer that is provided at an opposite side of the third light-emitting element with respect to the sealing layer and through which light from the third light-emitting element passes; and a fourth colored layer that is provided at an opposite side of the fourth light-emitting element with respect to the sealing layer and through which light from the fourth light-emitting element passes, in which the third colored layer may include a third flat surface at an opposite side of the sealing layer, a third side surface in contact with the fourth colored layer, and a third coupling surface inclined with respect to the third flat surface, coupling the third flat surface and the third side surface, and separated from the fourth colored layer, the fourth colored layer may include a fourth flat surface at an opposite side of the sealing layer, a fourth side surface in contact with the third side surface, and a fourth coupling surface inclined with respect to the fourth flat surface, coupling the fourth flat surface and the fourth side surface, and separated from the third colored layer, a contact portion between the third side surface and the fourth side surface may be in contact with the sealing layer, and the size of the third coupling surface in the perpendicular direction and the size of the fourth coupling surface in the perpendicular direction may be different from each other.

In this display device, the function as the lens can be changed by the third colored layer and the fourth colored layer.

An electronic apparatus according to an aspect includes the display device according to the aspect described above.

What is claimed is:

1. A display device comprising:
a substrate;
a first light-emitting element and a second light-emitting element provided at the substrate;
a sealing layer covering the first light-emitting element and the second light-emitting element;
a first colored layer that is provided at an opposite side of the first light-emitting element with respect to the sealing layer and through which light from the first light-emitting element passes; and
a second colored layer that is provided at an opposite side of the second light-emitting element with respect to the sealing layer and through which light from the second light-emitting element passes, wherein
the first colored layer includes
a first flat surface at an opposite side of the sealing layer,
a first side surface in contact with the second colored layer, and
a first coupling surface inclined with respect to the first flat surface, coupling the first flat surface and the first side surface, and separated from the second colored layer,
the second colored layer includes
a second flat surface at the opposite side of the sealing layer,
a second side surface in contact with the first side surface, and
a second coupling surface inclined with respect to the second flat surface, coupling the second flat surface and the second side surface, and separated from the first colored layer, and
a contact portion between the first side surface and the second side surface is in contact with the sealing layer.

2. The display device according to claim 1, further comprising:
a light-transmitting layer covering the first flat surface, the first coupling surface, the second flat surface, and the second coupling surface, wherein
a refractive index of the light-transmitting layer is different from a refractive index of the first colored layer and a refractive index of the second colored layer.

3. The display device according to claim 1, wherein
the first coupling surface and the second coupling surface have flat surfaces.

4. The display device according to claim 1, wherein
an angle formed by the first flat surface and the first coupling surface is different from an angle formed by the second flat surface and the second coupling surface.

5. The display device according to claim 1, wherein
the first coupling surface and the second coupling surface have curved surfaces.

6. The display device according to claim 1, wherein
a size of the first coupling surface in a perpendicular direction to the substrate is ⅓ or more of a thickness of the first colored layer.

7. The display device according to claim 6, wherein
a size of the second coupling surface in the perpendicular direction is ⅓ or more of a thickness of the second colored layer.

8. The display device according to claim 1, wherein
a size of the first coupling surface in a perpendicular direction to the substrate and a size of the second coupling surface in the perpendicular direction are different from each other.

9. The display device according to claim 8, further comprising:
a third light-emitting element and a fourth light-emitting element provided at the substrate and covered by the sealing layer;
a third colored layer that is provided at an opposite side of the third light-emitting element with respect to the sealing layer and through which light from the third light-emitting element passes; and
a fourth colored layer that is provided at an opposite side of the fourth light-emitting element with respect to the sealing layer and through which light from the fourth light-emitting element passes, wherein
the third colored layer includes
a third flat surface at the opposite side of the sealing layer,
a third side surface in contact with the fourth colored layer, and
a third coupling surface inclined with respect to the third flat surface, coupling the third flat surface and the third side surface, and separated from the fourth colored layer,
the fourth colored layer includes
a fourth flat surface at the opposite side of the sealing layer,
a fourth side surface in contact with the third side surface, and
a fourth coupling surface inclined with respect to the fourth flat surface, coupling the fourth flat surface and the fourth side surface, and separated from the third colored layer,
a contact portion between the third side surface and the fourth side surface is in contact with the sealing layer, and
a size of the third coupling surface in the perpendicular direction and a size of the fourth coupling surface in the perpendicular direction are different from each other.

10. An electronic apparatus comprising:
the display device according to claim 1.
